(19) United States
(12) Patent Application Publication
(10) Pub. No.: US 2023/0274953 A1
(43) Pub. Date: Aug. 31, 2023

(54) SUBSTRATE TREATMENT DEVICE AND METHOD FOR MANUFACTURING SEMICONDUCTOR DEVICE

(71) Applicant: KIOXIA CORPORATION, Tokyo (JP)

(72) Inventors: Tooru MIKAMI, Yokkaichi Mie (JP); Naoki KANDA, Yokkaichi Mie (JP); Hiroshi TOMITA, Yokkaichi Mie (JP)

(73) Assignee: KIOXIA CORPORATION, Tokyo (JP)

(21) Appl. No.: 18/148,375

(22) Filed: Dec. 29, 2022

(30) Foreign Application Priority Data
Feb. 28, 2022 (JP) 2022-029734
Aug. 25, 2022 (CN) 202211025010.1
Aug. 31, 2022 (JP) 2022-137918

(51) Int. Cl. H01L 21/67; H01L 21/673; H01L 21/677

(52) U.S. Cl. CPC H01L 21/67023; H01L 21/67069; H01L 21/67184; H01L 21/67196; H01L 21/67253; H01L 21/67379; H01L 21/67766; H01L 21/67778

(57) ABSTRACT

A substrate treatment device includes an EFEM unit, a cleaning and drying unit, and at least one load port unit, and the cleaning and drying unit includes a wafer holding mechanism, a transfer arm, a cleaning liquid supply nozzle, and a gas supply nozzle. The EFEM unit includes a transfer robot and a transfer arm capable of transferring a wafer between a load port unit of the at least one load port unit and the cleaning and drying unit, and the cleaning and drying unit is coupled to the EFEM unit in series with the load port unit.

### CROSS REFERENCE TO RELATED APPLICATIONS

This application is based upon and claims the benefit of priority from the prior Japanese Patent Applications No. 2022-029734 filed on Feb. 28, 2022 and No. 2022-137918 filed on Aug. 31, 2022 and Chinese Patent Application No. 202211025010.1 filed on Aug. 25, 2022, the entire contents of each of which are incorporated herein by their reference.

### FIELD

Embodiments described herein relate generally to a substrate treatment device and a method for manufacturing a semiconductor device.

### BACKGROUND

In a process where dry etching is performed on a substrate, such as a semiconductor wafer (hereinafter referred to as “wafer”), by using a corrosive gas, such as hydrogen bromide or chlorine, quality defects occur, such as deterioration of materials used for forming a device due to reactions with the corrosive gas or generation of particle in a FOUP (front opening unified pod). Further, in a treatment unit (a dry etching unit, for example) in which corrosive gas is used and another treatment unit (a film forming unit, for example) into which corrosive gas is brought via the FOUP, it is necessary to take a countermeasure for corrosion degradation and the like.

### BRIEF DESCRIPTION OF THE DRAWINGS

FIG. 1 is a schematic view describing one example of an entire structure of a semiconductor device manufacturing apparatus of a first embodiment;

FIG. 2 is a perspective view describing one example of a cleaning and drying unit in the first embodiment;

FIG. 3 is a schematic view of the cleaning and drying unit in a case where a plurality of wafer holding mechanisms and a plurality of cleaning and drying mechanisms are installed in a longitudinal direction;

FIG. 4 is a diagram describing a position where a wafer is stored in a load port unit and a position where a wafer is stored in the cleaning and drying unit;

FIG. 5 is a diagram describing the position where the wafer is stored in the load port unit and the position where the wafer is stored in the cleaning and drying unit;

FIG. 6 is a schematic view describing an installation adjustment mechanism of the cleaning and drying unit;

FIG. 7 is a schematic view of the wafer holding mechanism and the cleaning and drying mechanism;

FIG. 8 is a schematic view of a wafer holding stage;

FIG. 9A is a diagram describing one example of the wafer holding stage;

FIG. 9B is a diagram describing one example of the wafer holding stage;

FIG. 10 is a diagram describing a state where the wafer is transferred to an area above the wafer holding stage;

FIG. 11A is a diagram describing a series of steps from a transfer of the wafer to the cleaning and drying unit to cleaning of the wafer;

FIG. 11B is a diagram describing the series of steps from the transfer of the wafer to the cleaning and drying unit to the cleaning of the wafer;

FIG. 11C is a diagram describing the series of steps from the transfer of the wafer to the cleaning and drying unit to the cleaning of the wafer;

FIG. 11D is a diagram describing the series of steps from the transfer of the wafer to the cleaning and drying unit to the cleaning of the wafer;

FIG. 12 is a diagram describing a structure of a small module having three functions, that is, a function of supplying cleaning liquid, a function of supplying a drying gas, and a function of sucking the liquid and the gas;

FIG. 13 is a diagram describing one example of arrangement of the cleaning and drying mechanism in a modification;

FIG. 14 is a diagram describing a flow of water and drying gas at the time of cleaning the wafer in the modification;

FIG. 15 is a schematic view describing one example of an entire structure of a semiconductor device manufacturing apparatus of a second embodiment;

FIG. 16 is a perspective view describing one example of a substrate treatment device in the second embodiment;

FIG. 17 is a side view describing an example of arrangement of a cleaning and drying unit in the second embodiment;

FIG. 18 is a schematic view describing a sensor that measures physical properties of treatment liquid and a configuration around the sensor in a third embodiment;

FIG. 19 is a graph describing a relationship between a cleaning period and conductivity of treatment liquid;

FIG. 20 is a schematic view of a heater-equipped wafer holding mechanism of a cleaning and drying unit in a fourth embodiment;

FIG. 21 is a diagram describing one example of the heater-equipped wafer holding mechanism in the fourth embodiment;

FIG. 22 is a diagram describing one example of cleaning treatment in the fourth embodiment;

FIG. 23 is a plan view showing a configuration of a semiconductor device manufacturing system of a fifth embodiment;

FIG. 24 is a cross-sectional view showing a first example of a main treatment unit included in a manufacturing apparatus of the fifth embodiment; and

FIG. 25 is a cross-sectional view showing a second example of the main treatment unit included in the manufacturing apparatus of the fifth embodiment.

### DETAILED DESCRIPTION

A substrate treatment device of the present embodiment is a substrate treatment device including: a substrate-to-be-treated transfer box; a cleaning unit; and at least one load port. The cleaning unit includes a substrate-to-be-treated holding mechanism configured to be capable of holding a substrate to be treated, a cleaning liquid supply mechanism configured to be capable of supplying cleaning liquid onto the substrate to be treated held by the substrate-to-be-treated holding mechanism, and a gas supply mechanism configured to be capable of supplying gas onto the substrate to be treated held by the substrate-to-be-treated holding mechanism. The substrate-to-be-treated transfer box includes a substrate-to-be-treated transfer mechanism configured to be capable of transferring the substrate to be treated between a load port of the at least one load port and the cleaning unit, and the cleaning unit is coupled to the substrate-to-be-treated transfer box in series with the load port.

Hereinafter, embodiments of a semiconductor device manufacturing apparatus including a main treatment unit, a water cleaning and drying unit, and the like will be described in detail with reference to attached drawings. An example of the main treatment unit includes a dry etching unit. However, the main treatment unit is not limited to the dry etching unit. For example, a treatment unit relating to another process, such as a CVD (chemical etching deposition) unit, a sputtering unit, a wet etching unit, an annealing unit, a CMP (chemical mechanical polishing) unit, or an ion implantation unit, may be used as the main treatment unit.

### First Embodiment

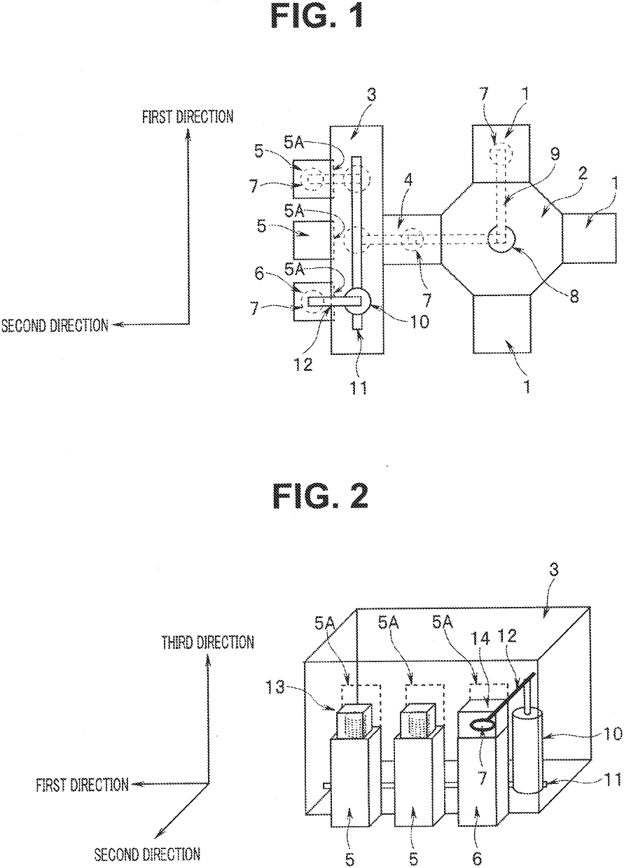

Hereinafter, a first embodiment will be described. FIG. 1 is a schematic view describing one example of an entire structure of a semiconductor device manufacturing apparatus of the first embodiment. The semiconductor device manufacturing apparatus includes dry etching units (dry etching chambers) 1, a vacuum transfer robot chamber 2, an EFEM (equipment front end module) unit 3, a load lock chamber 4, load port units 5, and a cleaning and drying unit (cleaning unit) 6. The dry etching units 1 serve as main treatment units. The EFEM unit 3 takes a wafer 7 from a FOUP 13 and supplies the wafer 7 to the main treatment unit 1, or the EFEM unit 3 retrieves the wafer 7 from the main treatment unit 1 and takes the wafer 7 to the FOUP 13. The wafer 7 is transferred between the vacuum transfer robot chamber 2 and the EFEM unit 3 in the load lock chamber 4. The FOUP 13 is placed on each load port unit 5 to bring the wafer 7 into a state where the wafer 7 can be transferred into the EFEM unit 3 in the load port unit 5.

The vacuum transfer robot chamber 2 includes a transfer robot 8. A transfer arm 9 is attached to the transfer robot 8. The transfer robot 8 and the transfer arm 9 serve as a substrate-to-be-treated transfer mechanism. A transfer robot 10 is provided in the EFEM unit 3. The transfer robot 10 can move on a rail 11. A transfer arm 12 is attached to the transfer robot 10. The transfer robot 10 and the transfer arm 12 serve as a substrate-to-be-treated transfer mechanism.

In the present embodiment, the cleaning and drying unit 6 and the load port units 5 are provided on the same side surface of the EFEM unit 3. That is, in the present embodiment, a plurality of load port units 5 and one cleaning and drying unit 6 are regularly arranged on one side surface of the EFEM unit 3. In other words, it is possible to understand that the substrate treatment device of the present embodiment is a device obtained by replacing any one of the load port units 5 with the cleaning and drying unit 6 in a configuration where the plurality of load port units 5 are provided on the EFEM unit 3. Alternatively, it is also possible to understand that the substrate treatment device of the present embodiment is a device where the EFEM unit 3 has a plurality of load port unit connection parts 5A, each configured to allow connection of the load port unit 5, the load port unit 5 is connected to at least one of the plurality of load port unit connection parts 5A, and the cleaning and drying unit 6 is connected to at least another of the plurality of load port unit connection parts 5A.

In the present embodiment, the plurality of (two) load port units 5 are regularly arranged on one side surface of the EFEM unit 3. The cleaning and drying unit 6 is disposed at a position in place of where the load port unit 5 would be installed, the position being adjacent to the EFEM unit 3. In the description made hereinafter, of directions parallel to a floor surface on which the substrate treatment device is installed, a direction which is a longitudinal direction of the EFEM unit 3 and in which the rail 11, which will be described later, extends is taken as a first direction. Of directions parallel to the floor surface on which the substrate treatment device is installed, a direction orthogonal to the first direction is taken as a second direction. Further, a direction orthogonal to the floor surface on which the substrate treatment device is installed is taken as a third direction.

In the first embodiment, the description will be made for an example in which the EFEM unit 3, designed to allow three load port units 5 to be mounted on the EFEM unit 3, is used in a semiconductor device manufacturing apparatus including the dry etching units that process wafers having a diameter of 300 mm. The EFEM unit 3 serving as a substrate-to-be-treated transfer box includes three load port unit connection parts 5A on which each load port unit 5 can be mounted. Of the three load port unit connection parts 5A, the load port unit 5 is attached to each of two load port unit connection parts 5A, and the cleaning and drying unit 6 is installed on a remaining load port unit connection part 5A in place of the load port unit 5. The cleaning and drying unit 6 (cleaning unit) is designed such that arrangement can be changed with respect to the load port units 5 and the EFEM unit 3. The cleaning and drying unit 6 is designed to have a lateral width equal to or less than a lateral width of the load port unit 5 (approximately 50 cm, for example) to prevent interference with the adjacent load port unit 5 in the first direction in FIG. 1. The cleaning and drying unit 6 is also designed such that, in the second direction, a relative position of a position, at which the wafer 7 is placed on a wafer support in the FOUP by the transfer robot 10 in the EFEM unit 3, from a load port access reference surface of the EFEM unit 3 is equivalent to a relative position of a support strut of the cleaning and drying unit 6 from the load port access reference surface of the EFEM unit 3. A perspective view showing the entire substrate treatment device of the present embodiment is shown in FIG. 2. FIG. 2 is a perspective view describing one example of the cleaning and drying unit in the first embodiment. The cleaning and drying unit 6 is installed adjacent to the EFEM unit 3 and in series with the load port units 5. In the third direction, a height of a cleaning and drying chamber 14 is set to be equal to a height of the FOUP 13 on the load port unit 5, thus achieving a configuration that allows the wafer 7 to be taken in and out by using the transfer robot 10 of the EFEM unit 3 without any change.

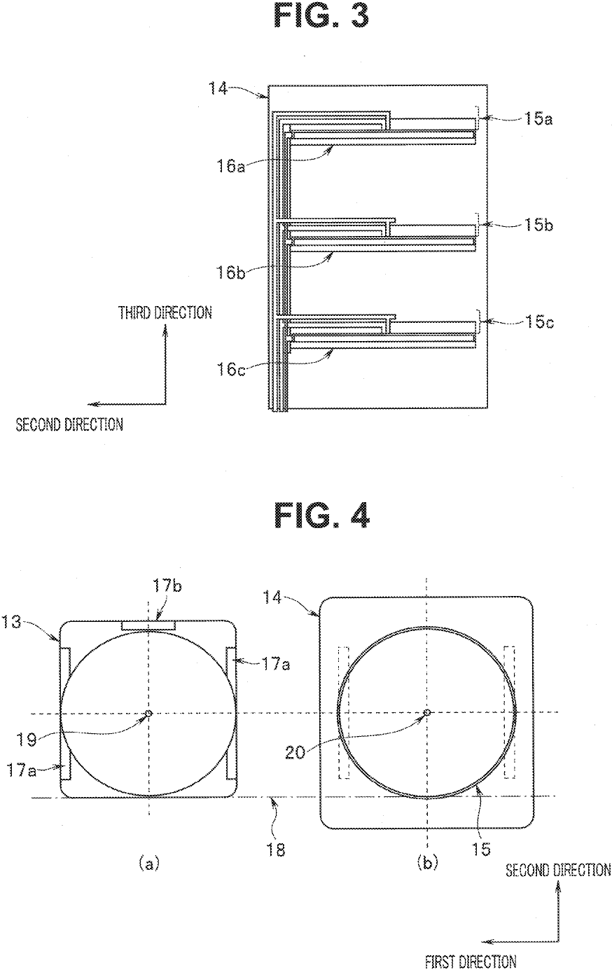

In a case where the semiconductor device manufacturing apparatus includes the dry etching units and a process period for dry etching is not long, a treatment period in the cleaning and drying unit 6 may affect process capacity of the entire semiconductor device manufacturing apparatus (for example, the treatment period in the cleaning and drying unit 6 may become a bottleneck). In this case, it is possible to include a plurality of wafer holding mechanisms 16 as substrate-to-be-treated holding mechanisms in the longitudinal direction (third direction). A cleaning and drying mechanism 15 is installed above each wafer holding mechanism 16. Accordingly, the wafers 7 placed on the respective wafer holding mechanisms 16 can be simultaneously cleaned, or simultaneously dried. That is, by performing single-wafer processing to each of a plurality of wafers 7 simultaneously, it is possible to reduce an effect on treatment capacity of the entire semiconductor device manufacturing apparatus. FIG. 3 is a schematic view showing the cleaning and drying unit 6 in the case where the plurality of wafer holding mechanisms 16 and the plurality of cleaning and drying mechanisms 15 are installed in the longitudinal direction. FIG. 3 shows three respective wafer holding mechanisms 16a, 16b, 16c. In the present embodiment, the wafer holding mechanisms 16 are not raised and lowered in the cleaning and drying chamber 14. Accordingly, a complicated operation mechanism is not required. By merely installing the plurality of wafer holding mechanisms 16, it is possible to avoid a situation where a treatment period in the cleaning and drying unit 6 affects treatment capacity of the entire semiconductor device manufacturing apparatus. FIG. 3 shows an example in which the three wafer holding mechanisms 16a, 16b, 16c are installed. However, a larger number of wafer holding mechanisms 16 may be installed provided that the wafer holding mechanisms 16 fit within a predetermined range. The predetermined range may be a range that corresponds to a length from a lowest shelf (slot 1) to a highest shelf (slot 25) in the FOUP, for example. A larger number of, for example, six, wafer holding mechanisms 16 may be installed by simplifying the wafer holding mechanisms 16 by a method which will be described later. Further, to cope with a configuration where a larger number of wafer holding mechanisms 16 are installed, a stroke of the transfer arm 12 of the transfer robot 10 in the EFEM unit 3 may be increased in the third direction.

A semiconductor device is manufactured by using a wafer made of a semiconductor material. The wafer has a diameter of 300 mm, for example. A plurality of 300 mm wafers are stored in the FOUP 13, and the FOUP 13 is automatically transferred between a plurality of main treatment devices. The 300 mm wafer is automatically transferred by the FOUP 13, and a position of the wafer in the FOUP and a position of the wafer on the load port unit 5 conform to the SEMI (semiconductor equipment and materials international) standard. With such a configuration, even if the FOUP 13, the load port unit 5, and the EFEM unit 3 have been made by different manufacturers, it is possible to combine the FOUP 13, the load port unit 5, and the EFEM unit 3 with compatibility. In the first embodiment, the position of the wafer denotes a position of the wafer in a lateral direction (first direction), a depth direction (second direction), and in a height direction (third direction). In the present embodiment, the cleaning and drying unit 6 is disposed on the EFEM unit 3 in a mode compatible with the load port unit 5. With such a configuration, the cleaning and drying unit 6 in the present embodiment can be used in a mode compatible with the FOUP 13, the load port unit 5, and the EFEM unit 3 that conform to the SEMI standard.

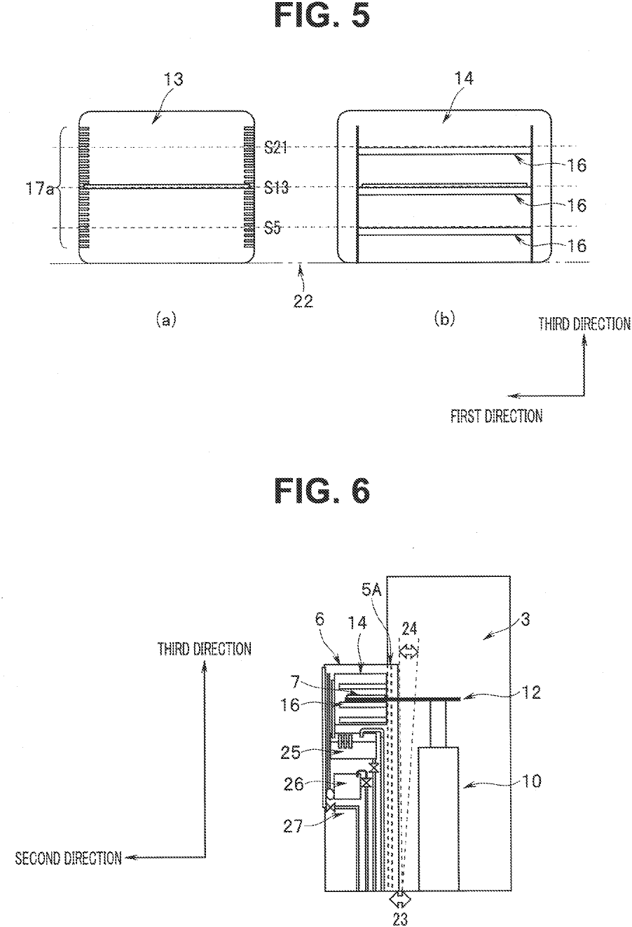

FIG. 4 and FIG. 5 are diagrams describing a position where a wafer is stored in the FOUP on the load port unit and a position where a wafer is stored in the cleaning and drying unit. In FIG. 4, (a) shows the position of the wafer in the FOUP 13 on the load port unit 5, and (b) shows the position of the wafer in the cleaning and drying chamber 14 of the cleaning and drying unit 6. FIG. 4 shows a comparison between the wafer in the FOUP 13 on the load port unit 5 and the wafer in the cleaning and drying chamber 14 of the cleaning and drying unit 6 as viewed from above. The FOUP 13 includes a pair of guides 17a and a guide 17b, the pair of guides 17a defining the position of the wafer in the lateral direction, the guide 17b defining the position of the wafer in the depth direction. The position of the wafer in the cleaning and drying chamber 14 in the lateral direction corresponds to the position of the wafer in the FOUP 13 in the lateral direction. The position of the wafer in the cleaning and drying chamber 14 in the depth direction also corresponds to the position of the wafer in the FOUP 13 in the depth direction. That is, in a case where an imaginary plane that passes through a boundary between the load port unit 5 and the EFEM unit 3 with the load port unit 5 being attached to the EFEM unit 3 is taken as a FOUP end reference surface 18, a distance in the second direction from the FOUP end reference surface 18 to a center 19 of the wafer in the FOUP 13 is substantially equal to a distance in the second direction from the FOUP end reference surface 18 to a center position 20 of the wafer in the cleaning and drying chamber 14. That is, the center 20 of the wafer in the cleaning and drying chamber 14 is geometrically at substantially the same position as the center 19 of the wafer in the FOUP 13 when viewed in the third direction. Further, an extension amount of the transfer arm 12 (transfer fork 304) of the transfer robot 10 in the second direction at the time of storing a wafer in the FOUP 13 is substantially equal to an extension amount of the transfer arm 12 (transfer fork 304) of the transfer robot 10 in the second direction at the time of storing a wafer in the cleaning and drying chamber 14 of the cleaning and drying unit 6. There may be a case where an operation of the transfer robot is adjusted according to individual differences in the load ports (such as differences due to different manufacturers). In the same manner, there may also be a case where an operation of the transfer robot is adjusted according to individual differences in the cleaning and drying unit 6. In the specification, “geometrically at substantially the same position when viewed in the third direction” is a concept including an adjustment range for managing the individual differences in the load ports or the cleaning and drying unit.

In the same manner as the position of the wafer in the FOUP 13, a left position and a right position of the wafer in the cleaning and drying chamber 14 in the lateral direction are also symmetrical, and a distance from the FOUP end reference surface 18 to the position of the wafer in the cleaning and drying chamber 14 in the depth direction is equal to a distance from the FOUP end reference surface 18 to the position of the wafer in the FOUP 13 in the depth direction with the load port unit 5 being normally attached. That is, the center position 20 of the wafer in the cleaning and drying chamber 14 matches the center 19 of the wafer in the FOUP 13. In the first embodiment, a phrase “same position” is used. However, it is necessary to have an adjustment range of the transfer robot for individual differences in load ports or differences due to different manufacturers. In the same manner, it is also necessary to have an adjustment range of the transfer robot for the cleaning and drying unit in the present embodiment.

Next, in FIG. 5, (a) shows the position of the wafer in the FOUP 13 on the load port unit 5, and (b) shows the position of the wafer in the cleaning and drying chamber 14 of the cleaning and drying unit 6. FIG. 5 shows a comparison between the wafer in the FOUP 13 on the load port unit 5 and the wafer in the cleaning and drying chamber 14 of the cleaning and drying unit 6 as viewed from the front. In FIG. 5, “S” denotes a slot. For example, “S5” denotes a slot 5.

As shown in (a), a plurality of pairs of left and right guides 17a are provided in the FOUP 13. In the present embodiment, 25 pairs of guides 17a are provided to form slot 1 to slot 25 for storing the wafer 7. As shown in (b), the cleaning and drying chamber 14 includes the plurality of wafer holding mechanisms 16. In the present embodiment, three wafer holding mechanisms 16 are provided, and upper surfaces of the wafer holding mechanisms 16 correspond to positions of slots 8, 13, 21, respectively. Distances from a FOUP bottom reference surface 22 to the upper surfaces of the wafer holding mechanisms 16 are set to be equal to distances from the FOUP bottom reference surface 22 to the slots 8, 13, 21 in the FOUP 13 to facilitate adjustment for transfer. Provided that interference with the cleaning and drying mechanisms 15 (a cleaning liquid supply mechanism and a gas supply mechanism) can be prevented, any of the slots 1 to 25 may be used. Further, the transfer robot can individually determine a transfer height and hence, it is possible to freely select a height of the transfer robot for a position of the slot or an intermediate position between slots.

By causing the position of the wafer in the cleaning and drying unit 6 in the lateral direction, the depth direction, and the height direction to match the position of the wafer in the FOUP in the lateral direction, the depth direction, and the height direction, the wafer can be transferred from the EFEM unit 3 to the cleaning and drying unit 6 without requiring a special function. In the same manner as a transfer of a wafer to another load port unit 5, the wafer can be transferred or returned by merely designating the position of the slot.

Each load port unit 5 is provided such that a relative position between the load port unit 5 and the EFEM unit 3 is adjustable. The cleaning and drying unit 6 is also provided such that a relative position between the cleaning and drying unit 6 and the EFEM unit 3 is adjustable. To be more specific, the cleaning and drying unit 6 in the present embodiment includes an installation adjustment mechanism equal to an installation adjustment mechanism of the load port unit 5 to allow the cleaning and drying unit 6 to be installed on the EFEM unit 3 in place of the load port unit 5. It is necessary to transfer a wafer to every slot of the load port unit 5 by using one transfer robot 10 and hence, it is necessary to adjust a distance from the transfer robot 10 and an inclination of the load port unit 5. In the present embodiment, the cleaning and drying unit 6 also includes the installation adjustment mechanism that can adjust a distance and an inclination at the time of installing the cleaning and drying unit 6 on the EFEM unit 3. FIG. 6 is a schematic view describing the installation adjustment mechanism of the cleaning and drying unit. The cleaning and drying unit 6 in the present embodiment includes a depth adjustment mechanism 23 and an inclination adjustment mechanism 24 as installation adjustment mechanisms. Specifically, the cleaning and drying unit 6 is fastened by screws at four portions, that is, an upper portion, a lower portion, a left portion, and a right portion at the time of attaching the cleaning and drying unit 6 to the EFEM unit 3, and the degree of fastening of the screws can be adjusted. As shown in FIG. 6 and FIG. 4, it is necessary to form the cleaning and drying chamber 14 with a size larger than a size of a 300 mm wafer. Therefore, the cleaning and drying unit 6 is not merely disposed next to the load port unit 5. The cleaning and drying unit 6 is designed such that a portion of the cleaning and drying chamber 14 enters the EFEM unit 3. The cleaning and drying unit 6 is also designed such that an end surface of a wafer corresponds to the FOUP end reference surface 18. By increasing a stroke of the transfer robot 10 in the EFEM unit 3 in a Y direction (second direction), it is possible to achieve an arrangement where the center position of the wafer is moved from the EFEM unit 3 to a position beyond an end of the load port unit 5. However, if the center position of the wafer is moved to an extreme far position, it is necessary to increase an extension and contraction amount of the transfer arm 12 of the transfer robot 10, so that it is also necessary to increase a size of the EFEM unit 3 itself. Therefore, such a position is not preferable. It is preferable to move the center position of the wafer up to a position that allows the cleaning and drying chamber 14 to be attached to a front panel of an EFEM without any change. The installation adjustment mechanism may be provided in the EFEM unit 3, or may be provided in each of the cleaning and drying unit 6 and the EFEM unit 3.

Next, processing sequence in the dry etching unit 1 will be described with reference to FIG. 1 and FIG. 2. The storage container (FOUP) 13 in which the wafer is stored is placed on the load port unit 5, is docked with the EFEM unit 3, and then opens a door. The wafer 7 in the FOUP 13 is taken out by the transfer robot 10 disposed in the EFEM unit 3, is delivered in the load lock chamber 4, and is then transferred to the vacuum transfer robot chamber 2. Thereafter, the wafer 7 is carried to the dry etching unit (dry etching chamber) 1 by the transfer robot 8. The transfer robot 10 can move on the rail 11 in a horizontal direction (first direction). When the transfer robot 10 rotates by using the third direction as a center axis, the transfer robot 10 can move the wafer 7 to the load port unit 5, the cleaning and drying unit 6, or the load lock chamber 4. The transfer robot 10 is equipped with the transfer arm 12, and the transfer arm 12 can be operated in the vertical direction. Accordingly, by extending and contracting the transfer arm 12 with the wafer 7 being placed on the transfer arm 12 and by lowering the transfer arm 12 to place the wafer 7 on the wafer holding mechanism 16, it is possible to place the wafer 7 at a predetermined position.

In the dry etching unit (dry etching chamber) 1, halogen gas, such as CF4, CH2Cl2, or HBr, is supplied and is decomposed by plasma, and the wafer 7 is irradiated with active ions to remove Si and the like by etching. After process treatment is performed, unreacted gas and decomposed halogen molecules may reside on the wafer 7.

As a comparison example, ashing treatment may be performed to remove a residual gas component such that O2 gas is decomposed by plasma in the dry etching unit (dry etching chamber) 1, thus being oxidized and removed. However, in this case, unintentional oxidation of Si, SiN, W, or the like may occur on the wafer 7, so that contact resistance may increase. Further, while cleaning with medicinal solution, such as HF, may be performed to remove the above-mentioned oxide, as it may affect a resulting dimension it may be difficult to perform ashing to the extent that residual halogen is sufficiently removed. In such a case, the wafer 7 to which residual halogen adheres due to treatment performed by the dry etching unit (dry etching chamber) 1 is returned to the EFEM unit 3 via the vacuum transfer robot chamber 2 without any change. Further, the wafer 7 to which residual halogen adheres is returned to the original FOUP 13 on the load port unit 5. Therefore, for example, after treatment, the residual halogen component may be volatilized from the wafer 7 and the FOUP 13 may be filled with the residual halogen component. In this case, when the wafer 7 is transferred to another manufacturing apparatus by the FOUP 13, the volatilized residual halogen component may be diffused in the EFEM unit 3. The diffused residual halogen component may react with moisture contained in atmosphere in the EFEM unit 3, thus becoming a corrosive gas, such as hydrochloric acid, and rusting a metal-made inner wall of the EFEM or a component of the transfer robot.

In view of the above, in the present embodiment, before the wafer 7 on which treatment was performed is returned to the FOUP 13 on the load port unit 5 from the EFEM unit 3, treatment is performed on the wafer 7 in the cleaning and drying unit 6. With such a configuration, residual halogen on the wafer 7 caused by the treatment performed by the dry etching unit (dry etching chamber) 1 is completely removed. Residual halogen and ammonia are easily dissolved in water and hence, it is possible to sufficiently remove residual halogen and ammonia by using water or warm water as cleaning liquid.

Next, a method for transferring a wafer to the cleaning and drying unit 6 will be described with reference to FIG. 3. The wafer 7 is placed on the wafer holding mechanism 16 of the cleaning and drying chamber 14 by using the transfer robot 10 in the EFEM unit 3. At this point of operation, the wafer 7 is carried out from the wafer holding mechanism 16 by the transfer robot 10 and the transfer arm 12 in the EFEM unit 3, and the wafer holding mechanism 16 itself is not moved but is fixed. As will be described later, it is necessary to move a wafer lift table and the cleaning and drying mechanism 15 in the vertical direction. However, it is not necessary to provide a large-sized driving mechanism for moving the wafer lift table and the cleaning and drying mechanism 15 in the vertical direction.

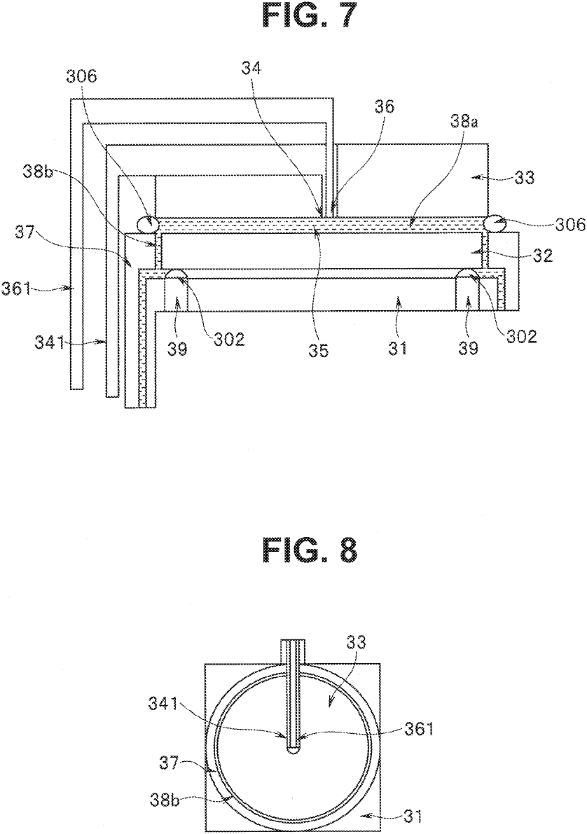

A cleaning and drying method will be described in detail with reference to FIG. 7. The cleaning and drying unit 6 includes at least one wafer holding mechanism 16 and at least one cleaning and drying mechanism 15. FIG. 7 is a schematic view of the wafer holding mechanism 16 and the cleaning and drying mechanism 15. The wafer holding mechanism 16 includes a wafer holding stage 31. The cleaning and drying mechanism 15 includes a facing member 33. The facing member 33 is installed above the wafer holding stage 31. The facing member 33 is formed into a disk shape, for example. A bottom surface of the facing member 33 faces an upper surface of a wafer 32 such that the bottom surface of the facing member 33 is parallel to the upper surface of the wafer 32. In this case, the bottom surface of the facing member 33 serves as a first surface. In a case where the wafer holding stage 31 is configured to fix the wafer 32 with the wafer 32 facing downward and the facing member 33 is installed below the wafer holding stage 31, an upper surface of the facing member 33 serves as the first surface. The wafer 32 is inserted between the wafer holding stage 31 and the facing member 33 by the transfer robot 10 of the EFEM unit 3 and, thereafter, is lowered in the downward direction, thus being installed on the wafer holding stage 31. Accordingly, it is possible to install the wafer 32 on the wafer holding stage 31 without moving the wafer holding stage 31.

Water as cleaning liquid is supplied to a center portion of the upper surface of the wafer 32 from a cleaning liquid supply nozzle 34 provided on a center portion of the bottom surface of the facing member 33. Water 35 supplied onto the wafer 32 spreads in a gap 38a formed between the upper surface of the wafer 32 and the bottom surface of the facing member 33, and is pushed toward an outer periphery of the wafer 32. The water 35 falling from the outermost periphery of the wafer 32 is drained downward through a gap 38b formed between a guide 37 and the wafer 32 and a gap formed between the wafer holding stage 31 and the guide 37. Thereafter, N2 gas as a gas is supplied to the center portion of the upper surface of the wafer 32 from a gas supply nozzle 36 provided on the center portion of the bottom surface of the facing member 33. With such operations, the water 35 remaining on the upper surface of the wafer 32 is expelled in a direction toward the outer periphery and is drained through the gap 38b formed between the guide 37 and the wafer 32 and the gap formed between the wafer holding stage 31 and the guide 37. Moisture remaining on the wafer 32 is evaporated and dried by supplying N2 gas as described above.

It is also possible to use warm water as the water 35. In a case where warm water is used, solubility of residual halogen increases, thus increasing ease of removal of residual halogen. For example, in a case where warm water is supplied in a manufacturing factory, a configuration may be adopted where the warm water is directly supplied to the cleaning and drying unit 6, and the warm water is supplied to the upper surface of the wafer 32 from the cleaning liquid supply nozzle 34. In a case where warm water is not supplied in the manufacturing factory, a water supply tank or a water supply pipe may be heated, water being supplied to the cleaning and drying unit 6 from the water supply tank or the water supply pipe. To be more specific, for example, water to be supplied to the cleaning and drying unit 6 may be heated by winding a heater around a pipe through which water is supplied to the cleaning and drying unit 6.

It is also possible to use N2 gas at high temperature as N2 gas. In a case where N2 gas at high temperature is used, it is possible to shorten a period required for evaporating and drying moisture. For example, in a case where N2 gas at high temperature is supplied in the manufacturing factory, a configuration may be adopted where the N2 gas at high temperature is directly supplied to the cleaning and drying unit 6, and the N2 gas at high temperature is supplied to the upper surface of the wafer 32 from the gas supply nozzle 36. In a case where N2 gas at high temperature is not supplied in the manufacturing factory, an N2 supply tank or an N2 supply pipe may be heated, the N2 gas being supplied to the cleaning and drying unit 6 from the N2 supply tank or the N2 supply pipe. To be more specific, for example, N2 gas to be supplied to the cleaning and drying unit 6 may be heated by winding a heater around a pipe through which N2 gas is supplied to the cleaning and drying unit 6.

The water 35 that is pushed out from the outermost periphery of the wafer 32 and is drained through the gap 38b formed between the guide 37 and the wafer 32 and the gap formed between the wafer holding stage 31 and the guide 37 is temporarily stored in a waste liquid tank 25 provided at a lower portion of the cleaning and drying chamber 14 (see FIG. 6). Treatment liquid stored in the waste liquid tank 25 is discarded at an appropriate timing (see FIG. 6). At this point of operation, a halogen gas component adhering to a surface of the wafer 32 is dissolved in water and is discarded. N2 gas supplied from the gas supply nozzle 36 also flows through the same passage as the water 35, and is discharged. With such operations, it is possible to evaporate and dry moisture remaining on the wafer 32. In FIG. 7 and the above-mentioned description, the nozzle 34 and the nozzle 36 form a double pipe, and the water 35 is supplied through an outer pipe and N2 gas is supplied through an inner pipe. However, the configuration is not limited to the above. For example, a configuration may be adopted where a common nozzle is used for the nozzle 34 and the nozzle 36, and a switching mechanism is provided at an intermediate portion of the pipe to supply the water 35 and N2 gas through the same nozzle.

FIG. 8 is a schematic view of the wafer holding stage 31. FIG. 8 is a schematic view of the wafer holding stage 31 as viewed from above the facing member 33. The facing member 33 has a hole that corresponds to the cleaning liquid supply nozzle 34, and a cleaning liquid supply pipe 341 is connected to the cleaning liquid supply nozzle 34. One end of the cleaning liquid supply pipe 341 is connected to the cleaning liquid supply nozzle 34. Another end of the cleaning liquid supply pipe 341 is connected to a water supply tank 26 provided at the lower portion of the cleaning and drying chamber 14 (see FIG. 6). The facing member 33 also has a hole that corresponds to the gas supply nozzle 36, and a gas supply pipe 361 is connected to the gas supply nozzle 36. One end of the gas supply pipe 361 is connected to the gas supply nozzle 36. Another end of the gas supply pipe 361 is connected to a drying N2 gas line 27 provided at the lower portion of the cleaning and drying chamber 14 (see FIG. 6).

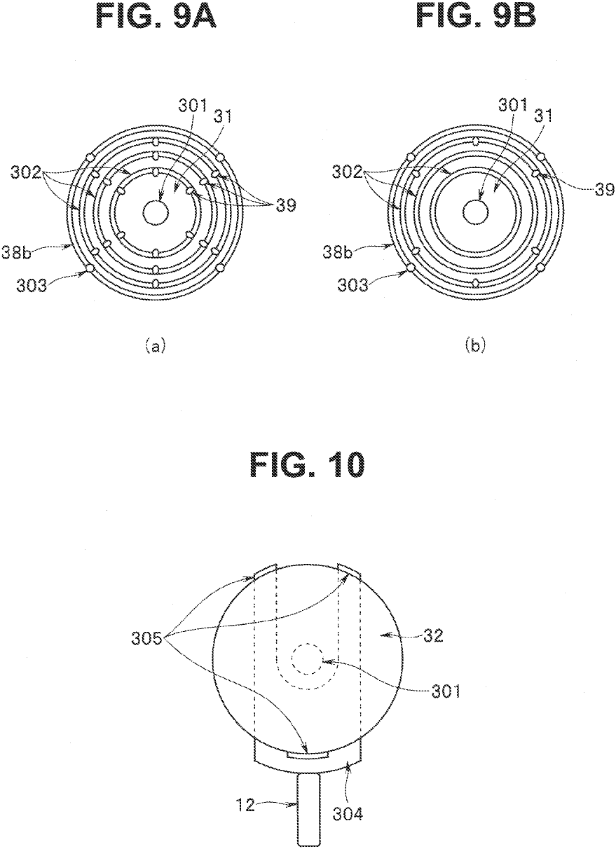

FIG. 9A and FIG. 9B are diagrams describing one example of the wafer holding stage 31. FIG. 10 is a diagram describing a state where the wafer 32 is transferred to an area above the wafer holding stage 31. FIG. 9A shows one example of the wafer holding stage 31 as viewed from above. A wafer lift table 301 is provided at the center of the wafer holding stage 31, and receives a wafer from the EFEM unit 3 from the transfer robot 10. The wafer holding stage 31 is a mechanism that receives the wafer 32 by moving the wafer lift table 301 in the vertical direction to place the wafer 32 on the wafer lift table 301 from the transfer fork 304 attached to a distal end of the transfer arm 12 shown in FIG. 10. A lip seal 306 is provided between the facing member 33 and the guide 37 to prevent the water 35, which flows through the gap 38a formed between the wafer 32 and the facing member 33, from seeping to a rear side of the guide 37. A plurality of ring-shaped lip seals 302 having different radii are attached to an upper surface of the wafer holding stage 31 in a concentric circular shape about the wafer lift table 301 to prevent the water 35, which flows through the gap 38b formed between the wafer 32 and the guide 37, from seeping to a rear surface of the wafer 32. Each lip seal 302 is provided with wafer inclination adjustment mechanisms 39 and hence, it is possible to adjust an inclination and a position (height) of the wafer 32 with respect to the facing member 33. The outermost lip seal 302 also has a function of preventing intrusion of water. The lip seals 302 disposed inward of the outermost lip seal 302 also have a function of preventing deflection of the wafer 32. Therefore, as shown in FIG. 9B, it is also possible to cause only the outer lip seal 302 to have a function of adjusting a position (height). In the present embodiment, sealing is provided between the facing member 33 and the wafer holding stage 31 by making use of a pressure of the water 35 released from the cleaning liquid supply nozzle 34, provided at a center portion of a lower surface of the facing member 33. However, to further increase sealability, the wafer holding stage 31 may be provided with a mechanism that chucks the wafer 32 by vacuum sucking.

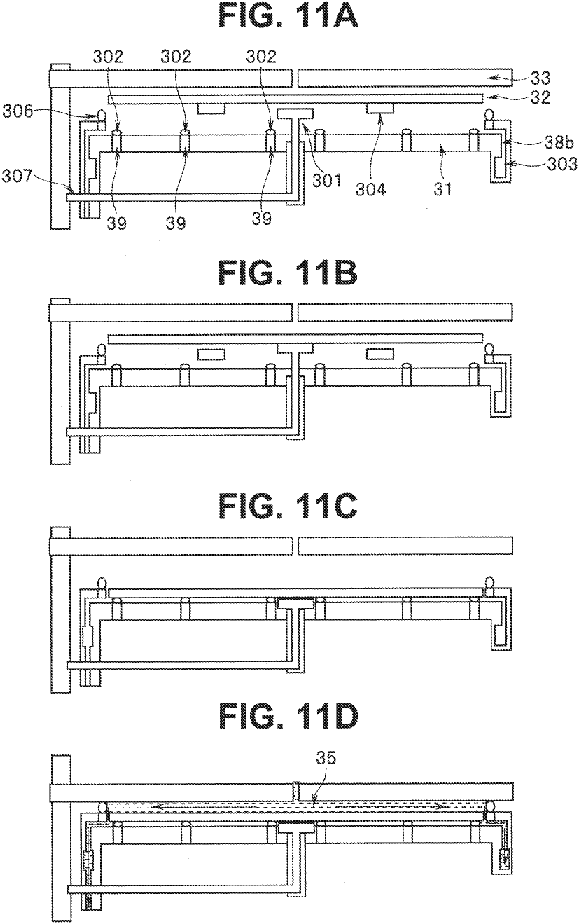

A series of steps from a transfer of a wafer to the cleaning and drying chamber 14 to cleaning of the wafer will be described with reference to FIG. 10 and FIG. 11A to FIG. 11D. The wafer 32 is on the transfer fork 304 attached to the distal end of the transfer arm 12 shown in FIG. 10. At this point of operation, to prevent the wafer 32 from falling from the transfer fork 304, the wafer 32 is held from a side surface by wafer fixing jigs 305 attached to the transfer fork 304. FIG. 11A to FIG. 11D are diagrams describing a series of steps from a transfer of the wafer to the cleaning and drying unit 6 to cleaning of the wafer. First, as shown in FIG. 11A, the transfer fork 304 holding the wafer 32 is inserted into the cleaning and drying chamber 14. At this point of operation, the facing member 33 is at an upper position to ensure a space into which the transfer fork 304 is inserted. Next, as shown in FIG. 11B, the wafer 32 is placed on the wafer lift table 301 by lowering the transfer fork 304. Then, as shown in FIG. 11C, the transfer fork 304 apart from the wafer 32 is returned to the EFEM unit 3 and, thereafter, the wafer lift table 301 is lowered by a wafer lift table raising and lowering mechanism 307 to place the wafer 32 on the lip seals 302, installed on the wafer holding stage 31. Lastly, as shown in FIG. 11D, the facing member 33 is lowered to reduce a separation between the facing member 33 and the wafer 32, and water is then supplied from a center nozzle. As shown by arrows, water flows toward an outer periphery from a center of the wafer 32. Water that flows beyond the outer periphery of the wafer 32 flows downward from the wafer 32, and is then drained from the cleaning and drying chamber 14 through a drain pipe 303. As described above, the cleaning and drying chamber 14 includes the multistage wafer holding stages 31, and each wafer holding stage 31 has a mechanism that adjusts a height of the wafer lift table 301 and that drains water. Accordingly, although a separation between the facing member 33 and the wafer 32 can be adjusted more easily by moving the facing member 33 in the vertical direction, it is also possible to adjust the separation between the facing member 33 and the wafer 32 by increasing the height of the wafer holding stage 31.

If water droplets remain on the bottom surface of the facing member 33 in the cleaning and drying chamber 14, the water droplets may drop on the wafer 32 at the time of performing drying treatment with N2 gas. Therefore, a hydrophobic material, such as a fluororesin, is used for the bottom surface of the facing member 33.

By using heated N2 at the time of performing drying treatment, it is possible to shorten a period required for drying treatment. Further, after the water 35 is supplied to the upper surface of the wafer 32 to clean the wafer 32, isopropyl alcohol (IPA) may be supplied to the upper surface of the wafer 32. With such an operation, it is possible to further shorten a period required for performing drying treatment with N2 gas.

In the present embodiment, each cleaning and drying mechanism 15 does not rotate or turn. In other words, in the present embodiment, when the wafer 32 is cleaned, a relative position between the cleaning liquid supply nozzle 34 and the wafer 32 is fixed. In the present embodiment, when the wafer 32 is dried, a relative position between the gas supply nozzle 36 and the wafer 32 is fixed. Therefore, in the present embodiment, it is unnecessary to move the wafer or the nozzle for the purpose of efficiently cleaning and drying the entire wafer having a large diameter of 300 mm. A teaching mechanism may be provided to slightly adjust a facing clearance and a facing angle between the wafer 32 and the facing member 33 of the cleaning and drying mechanism 15, for example.

In the present embodiment, the gap 38a formed between the facing member 33 and the wafer 32 is set such that the facing clearance between the facing member 33 and the wafer 32 is constant in a plane. To be more specific, a height and an inclination of the wafer 32 are adjusted by using the wafer inclination adjustment mechanisms 39 attached to the wafer holding stage 31. As shown in FIG. 9, by supporting the wafer 32 at three points with the wafer inclination adjustment mechanisms 39 substantially equidistantly installed to the lip seal 302 provided in the vicinity of the outer periphery of the wafer 32, it is possible to adjust the height and the inclination of the wafer 32, so that a gap (clearance) formed between the wafer 32 and the facing member 33 can be made uniform in a plane. In this description, the height of the wafer 32 is directly adjusted. However, a method may be used where the position of the wafer is adjusted by adjusting a height of the holding stage and a height of a portion of the holding stage, and it is sufficient to have a function of adjusting a gap.

Next, a comparison example of the present embodiment will be described. In the comparison example, cleaning with O2 gas plasma is performed after dry etching is performed. In the comparison example, for example, residual corrosive gas on a substrate may be removed by sputtering through cleaning with O2 gas plasma at a high temperature of 300° C. or more. However, when treatment is performed at a high temperature, unintended oxidation may occur on Si in the wafer or on a metal material, thus affecting variations in the shape of the device or electric characteristics. For this reason, such cleaning may not be applicable. In addition, when the above-mentioned oxide film is removed in a later step, trapped corrosive gas may be emitted, thus causing quality defects, or thus permeating into polymer, being a material used for forming the FOUP, leading to transfer of the gas to a wafer when FOUP is used in another step. That is, it is difficult to completely remove a deposit on the substrate by performing cleaning with O2 gas plasma.

As another comparison example, a cleaning treatment unit (cleaning treatment chamber) may be provided to the vacuum transfer robot chamber 2 in addition to the dry etching units (dry etching chambers) 1 in the semiconductor device manufacturing apparatus (the semiconductor device manufacturing apparatus may be provided as a so-called clustered device). However, the clustered device has lower wafer treatment capacity or has a significantly larger size compared with a configuration where only dry etching units (dry etching chambers) 1 are provided.

As still another comparison example, a rotary water cleaning unit may be provided next to the EFEM unit 3. The rotary cleaning unit rotates a wafer at high speed to increase dust removal performance at the time of supplying water or medicinal solution and to perform shaking drying, for example. However, to rotate the wafer at high speed, a large rotary shaft having rigidity is required to prevent shift of the rotary shaft. A wafer sucking mechanism is also required to prevent the wafer from flying away and breaking due to rotation at high speed. Further, in the case where the wafer is rotated at high speed, water or medicinal solution splashing on the outside of the wafer may impinge on and rebound from an inner wall of the cleaning treatment unit (cleaning chamber), and then may adhere to the wafer again. To prevent such a phenomenon, it is necessary to increase a distance between the wafer and the inner wall of the cleaning treatment unit (cleaning chamber), or it is necessary to install a splash prevention plate.

As still another comparison example, instead of rotating the wafer, a cleaning nozzle may be moved to uniformly clean a wafer. However, such configuration tends to increase the size. In any of the above-mentioned comparison examples, the size of the cleaning treatment unit (cleaning chamber) is not reduced and hence, it is difficult to install such a cleaning unit in the vicinity of the EFEM unit 3 without any change.

In a case where two or more dry etching units (dry etching chambers) are provided in the semiconductor device manufacturing apparatus, capacity of just one cleaning and drying unit 6 may not be sufficient, thus increasing a period required for wafer treatment. It may be possible to consider a configuration where a plurality of substrates, each disposed horizontally, are stacked in the vertical direction, and are cleaned collectively. However, in this case, the cleaning chamber is required to rotate a wafer holding member at high speed while supplying medicinal solution and hence, the size of the cleaning chamber increases.

In the above-mentioned embodiment, by limiting capacity of the cleaning and drying unit 6 not to capacity of removing dust on a wafer, but to minimum capacity required to remove residual gas component, a wafer rotating mechanism, a holding member raising and lowering function, and a nozzle turning function are omitted from the cleaning and drying unit 6. Accordingly, in the present embodiment, it is possible to reduce the size of the cleaning and drying unit 6. Therefore, it is possible to achieve the cleaning and drying unit 6 having cleaning capacity at a level that can remove the residual gas component on a wafer generated in the dry etching unit (dry etching chamber) 1, serving as the main treatment unit, the cleaning and drying unit 6 being reduced in size at a level that allows the cleaning and drying unit 6 to be installed in the EFEM unit 3 or at the load port unit connection part 5A.

Next, a constitutional example of the cleaning and drying unit of a modification of the first embodiment is shown. As shown in FIG. 12, the cleaning and drying unit of the modification is formed by combining a plurality of small modules having a function of supplying cleaning liquid, a function of supplying drying gas, and a function of sucking liquid and gas. As shown in FIG. 12, the cleaning and drying unit of the modification includes a fixed wafer holding stage 41 and a plurality of fixed small-sized cleaning and drying modules (small modules) 43. A supply pipe 441 for water and drying gas (N2 gas) and a drain pipe 461 for draining water and discharging drying gas (N2 gas) are connected to an upper surface of each small module 43.

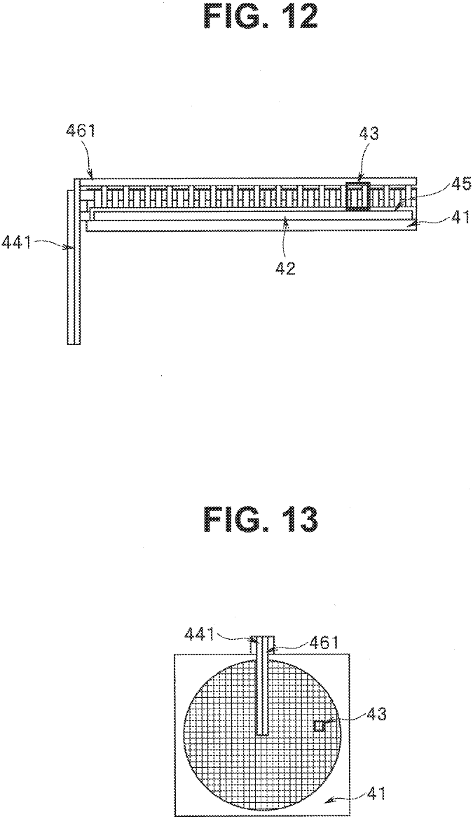

The plurality of small modules 43 are disposed directly above and close to the wafer holding stage 41 and a wafer 42, and serve as a cleaning and drying mechanism (the cleaning liquid supply mechanism and the gas supply mechanism). The plurality of small modules 43 do not rotate or turn. As shown in FIG. 13, for example, the plurality of small modules 43 are arranged in a lattice shape to cover the entire wafer 42. FIG. 13 is a diagram describing one example of the arrangement of the cleaning and drying mechanism in the modification. FIG. 13 is a schematic view of the wafer holding stage 41 when viewed from above the small modules 43.

A flow of water will be described with reference to FIG. 14. FIG. 14 is a diagram describing the flow of water and drying gas at the time of cleaning the wafer in the modification. Each small module 43 includes a center nozzle 44 and sucking nozzles 46. The center nozzle 44 extending in the third direction has an opening at one end that faces the wafer 42. The center nozzle 44 is disposed at a center of a surface of the small module 43, the surface facing the wafer 42. Another end of the center nozzle 44 is connected with the supply pipe 441. Each sucking nozzle 46 extending in the third direction has an opening at one end that faces the wafer 42. The sucking nozzles 46 are disposed to surround the center nozzle 44 on the surface of the small module 43 that faces the wafer 42. Another end of each sucking nozzle 46 is connected with the drain pipe 461. Water is supplied from the center nozzle 44 connected to the supply pipe 441, and water 45 on the wafer 42 is drained through the sucking nozzles 46 connected to the drain pipe 461. Next, N2 gas is supplied from the center nozzle 44, and is then discharged from the sucking nozzles 46.

A supply switching part (not shown in the drawing) is connected to one end of the supply pipe 441 that is not connected to the center nozzle 44, and a water supply pipe (not shown in the drawing) and a gas supply pipe (not shown in the drawing) are connected to the supply switching part, cleaning water being supplied through the water supply pipe, drying gas being supplied through the gas supply pipe. Connection of the pipe is switched by the supply switching part such that the supply pipe 441 is connected with the water supply pipe at the time of supplying water from the center nozzle 44, and the supply pipe 441 is connected with the gas supply pipe at the time of supplying N2 gas from the center nozzle 44. The drain pipe 461 also has substantially the same structure, and a connection destination of the drain pipe 461 is switched between draining water and discharging N2 gas. Each small module 43 individually cleans and dries only a gap portion between the small module 43 and the wafer 42, that is, only a surface of the wafer 42 that faces the small module 43. It is also possible to individually adjust an amount of water used for cleaning for each small module 43 or each block including a plurality of small modules 43.

### Second Embodiment

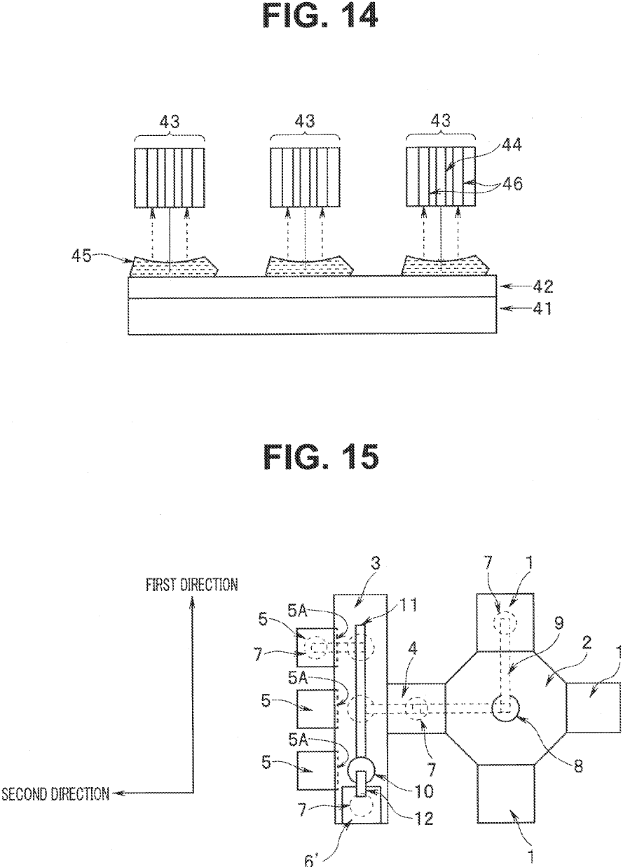

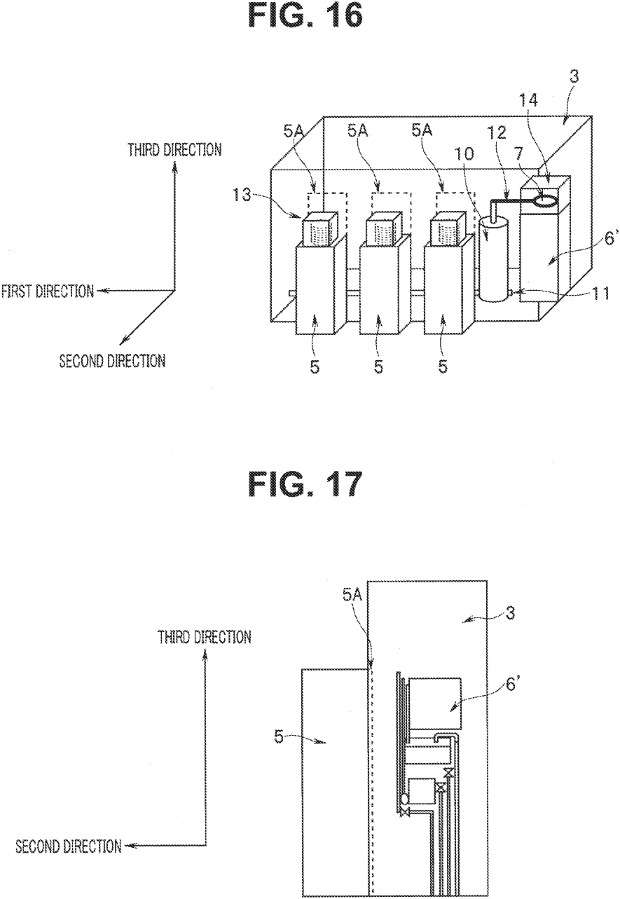

Hereinafter, a second embodiment will be described. FIG. 15 is a schematic view describing one example of an entire structure of a semiconductor device manufacturing apparatus of the second embodiment of the present invention. The second embodiment differs from the first embodiment with respect to a point that a cleaning and drying unit 6′ is not installed at the load port unit connection part 5A of the EFEM unit 3, but is installed in the EFEM unit 3. The rest of configuration and processing sequence are identical to the corresponding configuration and processing sequence in the first embodiment. FIG. 16 is a perspective view of a substrate treatment device. FIG. 17 is a side view describing an example of arrangement of the cleaning and drying unit 6′. In the second embodiment, the cleaning and drying unit 6′ is installed in a state of being housed in the EFEM unit 3.

In FIG. 17, the cleaning and drying unit 6′ is installed in the vicinity of a center of the EFEM unit 3 in a paper surface direction (second direction). However, the cleaning and drying unit 6′ may be installed at a left end (load port unit 5 side) of the EFEM unit 3 in the paper surface direction, or may be installed at a right end (vacuum transfer robot chamber 2 side) of the EFEM unit 3 in the paper surface direction. When a size of the cleaning and drying unit 6′ is set to be equal to or less than a width of 50 cm and a depth of 80 cm, for example, the cleaning and drying unit 6′ can be incorporated into a commercially available EFEM unit without special alteration and hence, the cleaning and drying unit 6′ can be used without changing design. Accordingly, such a configuration is preferable.

In the case where the cleaning and drying unit 6′ is installed in the EFEM unit 3 as in the case of the second embodiment, unlike the first embodiment, it is possible to configure the semiconductor device manufacturing apparatus without reducing the number of load port units 5 coupled to the EFEM unit 3. Accordingly, it is possible to manufacture a semiconductor device more efficiently.

### Third Embodiment

Hereinafter, a third embodiment will be described. A cleaning and drying unit in the third embodiment is provided with sensors (such as a conductivity meter and a PH meter) that measure physical properties (such as conductivity and PH) of treatment liquid (cleaning liquid after cleaning a wafer, for example). By measuring the physical properties of treatment liquid by the sensors and by determining a processing state (a progress state of a wafer cleaning step, for example) based on the measured physical properties, it is possible to detect an end point of the wafer cleaning step based on the measured physical properties. Either one of the configuration in the first embodiment or the configuration in the second embodiment is applicable for the configuration of the cleaning and drying unit other than the sensors.

Hereinafter, measuring sequence will be described with reference to FIG. 18 by focusing on a point that makes the third embodiment different from the first embodiment and the second embodiment. FIG. 18 is a schematic view describing the sensor that measures physical properties of treatment liquid and the configuration around the sensor in the third embodiment. As shown in FIG. 18, in the cleaning and drying unit in the third embodiment, cleaning liquid flows through an upper surface of the wafer and, thereafter, flows through a drain pipe 52 from a cleaning and drying unit 51, and then flows into a sensor (conductivity meter) 53.

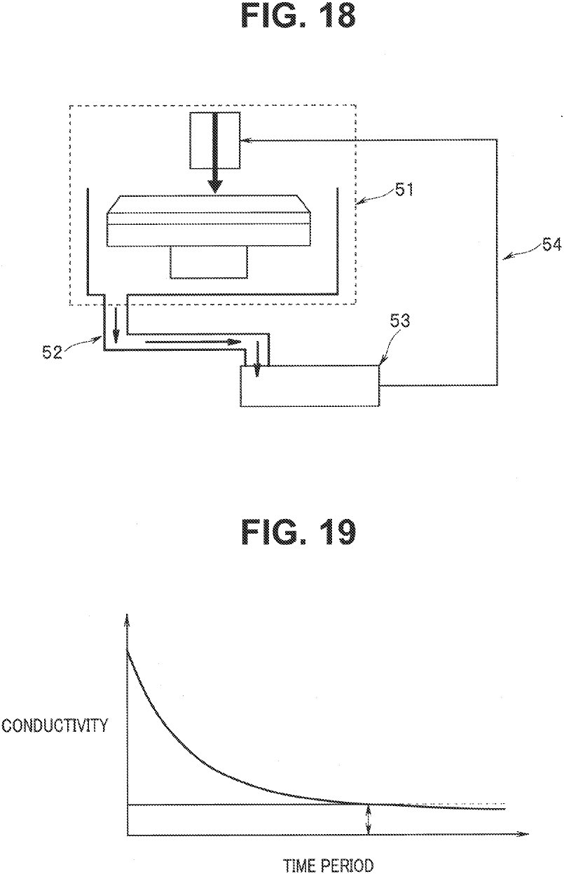

FIG. 19 is a graph describing a relationship between a cleaning period and conductivity of treatment liquid. In a case where water is used as cleaning liquid, as shown in FIG. 19, immediately after the cleaning step is started, a large amount of halogen (Cl, F, Br) is dissolved in water, so that conductivity measured by the sensor 53 is high. However, an amount of residual halogen on the wafer gradually reduces along with the progress of the cleaning step and hence, conductivity measured by the sensor 53 approaches conductivity of pure water. At a point of time when conductivity measured by the sensor 53 becomes equal to or less than a determined threshold, a control signal is transmitted via a control signal line 54 to end the cleaning step. As described above, in the cleaning and drying unit in the third embodiment, physical properties of treatment liquid are measured and hence, it is possible to automatically end the cleaning step according to a progress state. With such a configuration, for example, it is possible to set a long period for a cleaning step for a wafer having a large amount of residual halogen, and it is possible to set a short period for a cleaning step for a wafer having a relatively small amount of residual halogen. Accordingly, it is possible to reduce a use amount of cleaning liquid and a period required for the cleaning step without lowering a cleaning effect.

### Fourth Embodiment

Hereinafter, a fourth embodiment will be described.

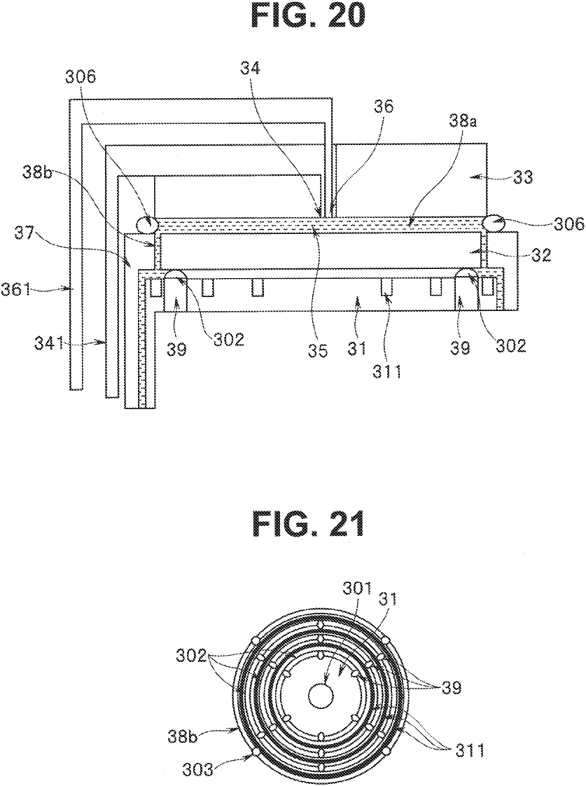

FIG. 20 is a schematic view showing a heater-equipped wafer holding mechanism in the fourth embodiment. FIG. 21 is a diagram describing one example of the heater-equipped wafer holding mechanism. FIG. 22 is a diagram describing one example of cleaning treatment in a case where the heater-equipped wafer holding mechanism is used.

As shown in FIG. 20, in the wafer holding mechanism in the fourth embodiment, a plurality of heaters 311 are installed on an upper surface of the wafer holding stage 31. As shown in FIG. 21, the plurality of heaters 311 are installed at positions that do not interfere with the lip seal 302, for example.

As shown in FIG. 22, the water 35 is supplied to an upper surface of the wafer 32 to clean the wafer 32. Thereafter, to dry moisture remaining on the wafer 32, N2 gas is supplied to the upper surface of the wafer 32. In the fourth embodiment, when N2 gas is supplied to the upper surface of the wafer 32, the wafer 32 is heated by using the heaters 311. With such a configuration, it is possible to shorten a period required for drying moisture.

Also in the fourth embodiment, isopropyl alcohol (IPA) may be supplied to the upper surface of the wafer 32 after the water 35 is supplied to the upper surface of the wafer 32 to clean the wafer 32. With such a configuration, it is possible to further shorten a period required for drying moisture with N2 gas.

### Fifth Embodiment

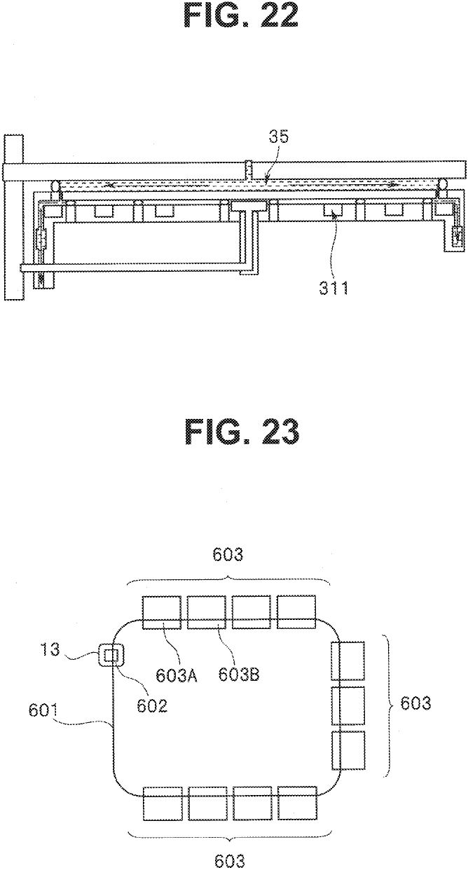

FIG. 23 is a plan view showing a configuration of a semiconductor device manufacturing system of a fifth embodiment.

The manufacturing system of the present embodiment includes a track (ceiling track) 601, a transfer vehicle (ceiling traveling transfer vehicle) 602, and a plurality of manufacturing apparatuses 603, the transfer vehicle 602 being movable along the track 601, the plurality of manufacturing apparatuses 603 being arranged close to the track 601.

The track 601 is installed on a ceiling of a manufacturing factory, for example. In this case, the transfer vehicle 602 serves as a ceiling traveling transfer vehicle. However, a position where the track 601 is installed is not limited to a ceiling. For example, the track 601 may be installed on a floor (ground) of the manufacturing factory, or may be installed on a wall surface of the manufacturing factory. Further, it is not always necessary for the transfer vehicle 602 to include wheels. In this case, the transfer vehicle 602 may be driven by a linear motor, for example.

Each manufacturing apparatus 603 has a configuration substantially equal to the configuration of the semiconductor device manufacturing apparatus described in the first embodiment, for example. However, the configuration of each manufacturing apparatus 603 is not limited to the above. For example, a configuration substantially equal to the configuration of the semiconductor device manufacturing apparatus described in another embodiment and/or a configuration substantially equal to the configuration of the cleaning and drying unit may be applied.

For example, one manufacturing apparatus 603A includes, as the main treatment unit 1, a dry etching unit capable of performing dry etching, being a first process, and another manufacturing apparatus 603B includes, as the main treatment unit 1, a film forming unit (a sputtering unit or a CVD unit) capable of performing film forming, being a second process. An example of the combination of the first process and the second process is not limited to the above. Each of the first process and the second process may be any process of wet etching, annealing, CMP, or ion implantation, for example. Further, the first process and the second process may be processes of the same kind, for example. The first process may be film forming that uses a first material, and the second process may be film forming that uses a second material, for example.

FIG. 24 shows a dry etching unit as a first example of the main treatment unit 1. The dry etching unit includes, for example, a chamber 81, a wafer holder 82, and an ion source 83. The wafer holder 82 holds the wafer 7 accommodated in the chamber 81. The ion source 83 irradiates the wafer 7 with ion to perform dry etching of the wafer 7.

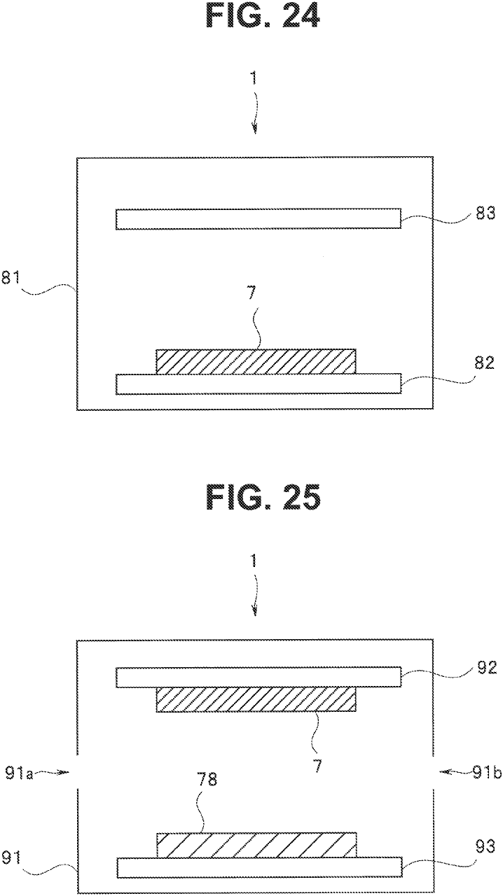

FIG. 25 shows a film forming unit (sputtering unit) as a second example of the main treatment unit 1. The film forming unit (sputtering unit) includes a chamber 91, a wafer holder 92, and a target holder 93. The chamber 91 has an air supply port 91a and a discharge port 91b, film-forming gas being supplied from the air supply port 91a, unnecessary gas being discharged from the discharge port 91b. The wafer holder 92 holds the wafer 7 accommodated in the chamber 91. The target holder 93 holds a film-forming target 78.

The FOUP 13 is mounted on the transfer vehicle 602 in a state of storing the wafer 7. The FOUP 13 mounted on the transfer vehicle 602 is transferred along the track 601, and is placed on the load port unit 5 of each manufacturing apparatus 603 (for example, the manufacturing apparatus 603A including the dry etching unit as the main treatment unit 1) from the transfer vehicle 602. For example, as described in the first embodiment, the wafer 7 is taken out from the FOUP 13, placed on the load port unit 5, by the transfer robot 10, and is transferred to the vacuum transfer robot chamber 2 via the load lock chamber 4. The wafer 7 transferred to the vacuum transfer robot chamber 2 is carried to the main treatment unit 1 by the transfer robot 8, and treatment (dry etching, for example) is performed by the main treatment unit 1. The wafer 7 on which treatment is performed by the main treatment unit 1 is carried to the cleaning and drying unit 6 by the transfer robot 8 and the transfer robot 10, and is cleaned and dried by the cleaning and drying unit 6. The wafer 7 cleaned and dried by the cleaning and drying unit 6 is stored in the FOUP 13, placed on the load port unit 5, by the transfer robot 10.

The FOUP 13 is mounted on the transfer vehicle 602 in a state of storing the wafer 7, cleaned and dried by the cleaning and drying unit 6, is transferred along the track 601, and is placed on the load port unit 5 of another manufacturing apparatus 603 (for example, the manufacturing apparatus 603B including the film forming unit as the main treatment unit 1). The wafer 7 is carried to the main treatment unit 1 by the transfer robot 10 and the transfer robot 8 from the FOUP 13 placed on the load port unit 5, and treatment (sputtering, for example) is performed by the main treatment unit 1. The wafer 7 on which treatment is performed by the main treatment unit 1 is carried to the cleaning and drying unit 6 by the transfer robot 8 and the transfer robot 10, and is cleaned and dried by the cleaning and drying unit 6. The wafer 7 cleaned and dried by the cleaning and drying unit 6 is stored in the FOUP 13, placed on the load port unit 5, by the transfer robot 10.

The FOUP 13 is mounted on the transfer vehicle 602 in a state of storing the wafer 7, cleaned and dried by the cleaning and drying unit 6, is transferred along the track 601, and is placed on the load port unit 5 of still another manufacturing apparatus 603, for example.

In the present embodiment, after treatment is performed on the wafer 7 by using the main treatment unit 1 in each manufacturing apparatus 603 and before the wafer 7 is stored in the FOUP 13, simple cleaning and drying treatment can be performed on the wafer 7 by the cleaning and drying unit 6. With such a configuration, it is possible to maintain the FOUP 13 and other manufacturing apparatuses 603 in a clean state.

While certain embodiments have been described, these embodiments have been presented by way of example only, and are not intended to limit the scope of the inventions. Indeed, the novel devices and systems described herein may be embodied in a variety of other forms; furthermore, various omissions, substitutions and changes in the form of the devices and systems described herein may be made without departing from the spirit of the inventions. The accompanying claims and their equivalents are intended to cover such forms or modifications as would fall within the scope and spirit of the inventions.

What is claimed is:

1. A substrate treatment device comprising:
a substrate-to-be-treated transfer box;
a cleaning unit; and
at least one load port, wherein
the cleaning unit includes
a substrate-to-be-treated holding mechanism configured to be capable of holding a substrate to be treated,
a cleaning liquid supply mechanism configured to be capable of supplying cleaning liquid onto the substrate to be treated held by the substrate-to-be-treated holding mechanism, and
a gas supply mechanism configured to be capable of supplying gas onto the substrate to be treated held by the substrate-to-be-treated holding mechanism,
the substrate-to-be-treated transfer box includes a substrate-to-be-treated transfer mechanism configured to be capable of transferring the substrate to be treated between a load port of the at least one load port and the cleaning unit, and
the cleaning unit is coupled to the substrate-to-be-treated transfer box in series with the load port.

2. The substrate treatment device according to claim 1, wherein
the substrate-to-be-treated transfer box further includes a railway extending in a first direction,
the substrate-to-be-treated transfer mechanism includes
a base movable on the railway,
an extension and contraction arm attached onto the base in a rotatable manner, a protruding amount of the extension and contraction arm from the base in a second direction orthogonal to the first direction being adjustable, and
a holding part provided on a distal end side of the extension and contraction arm, and configured to be capable of holding the substrate to be treated,
at least one of the at least one load port is coupled to the substrate-to-be-treated transfer box, and
assuming that a storage position of the substrate to be treated with a substrate-to-be-treated container being attached to the load port is taken as a first storage position, and
a storage position of the substrate to be treated in a state of being cleaned by the cleaning unit is taken as a second storage position,
a distance from the railway to the first storage position in the second direction is equal to a distance from the railway to the second storage position in the second direction.

3. The substrate treatment device according to claim 2, wherein
the substrate-to-be-treated transfer box includes a plurality of load port connection parts,
the load port is connected to at least one of the plurality of load port connection parts,
the cleaning unit is connected to at least another of the plurality of load port connection parts, and
the substrate-to-be-treated transfer mechanism is capable of transferring the substrate to be treated from the load port to the substrate-to-be-treated holding mechanism.

4. The substrate treatment device according to claim 1, wherein
the cleaning unit is provided such that a relative position between the cleaning unit and the substrate-to-be-treated transfer box is adjustable.

5. The substrate treatment device according to claim 2, wherein
an extension amount of the holding part in the second direction at a time of storing the substrate to be treated in the substrate-to-be-treated container is equal to an extension amount of the holding part in the second direction at a time of storing the substrate to be treated in the cleaning unit.

6. The substrate treatment device according to claim 2, wherein
a plurality of the first storage positions are provided in a third direction orthogonal to the first direction and the second direction, and
a position of the second storage position in the third direction is equal to a position of any one of the plurality of the first storage positions in the third direction.

7. The substrate treatment device according to claim 2, wherein
the cleaning unit further includes
a second substrate-to-be-treated holding mechanism provided at a position apart from the substrate-to-be-treated holding mechanism in a third direction orthogonal to the first direction and the second direction,
a second cleaning liquid supply mechanism configured to be capable of supplying the cleaning liquid onto a second substrate to be treated held by the second substrate-to-be-treated holding mechanism, and
a second gas supply mechanism configured to be capable of supplying the gas onto the second substrate to be treated held by the second substrate-to-be-treated holding mechanism,
the cleaning unit is capable of simultaneously cleaning the substrate to be treated held by the substrate-to-be-treated holding mechanism, and
the cleaning unit is capable of cleaning the second substrate to be treated held by the second substrate-to-be-treated holding mechanism during cleaning of the substrate to be treated.

8. The substrate treatment device according to claim 1, wherein
the cleaning liquid supply mechanism is capable of supplying the cleaning liquid to an upper surface of the substrate to be treated for a first predetermined period with a relative position between the cleaning liquid supply mechanism and the substrate to be treated being fixed, and
the gas supply mechanism is capable of supplying the gas to the upper surface of the substrate to be treated for a second predetermined period with a relative position between the gas supply mechanism and the substrate to be treated being fixed.

9. The substrate treatment device according to claim 8, wherein
the cleaning unit further includes at least one functional component,
the at least one functional component includes
the cleaning liquid supply mechanism,
the gas supply mechanism, and
a sucking mechanism configured to be capable of sucking the cleaning liquid and the gas, and
the at least one functional component includes a plurality of functional components, and the plurality of functional components are disposed to face the upper surface of the substrate to be treated at least during the first predetermined period or the second predetermined period.

10. The substrate treatment device according to claim 1, wherein
the cleaning liquid supply mechanism is further capable of supplying isopropyl alcohol onto the substrate to be treated after the cleaning liquid is supplied onto the substrate to be treated.

11. The substrate treatment device according to claim 1, wherein
the gas includes a nitrogen gas.

12. The substrate treatment device according to claim 1, wherein
the cleaning unit further includes a facing member having a first surface that faces an upper surface of the substrate to be treated at a time of the substrate to be treated being stored in the cleaning unit,
the cleaning liquid supply mechanism is capable of supplying the cleaning liquid to between the first surface of the facing member and the upper surface of the substrate to be treated, and the gas supply mechanism is capable of supplying the gas to between the first surface of the facing member and the upper surface of the substrate to be treated, and
the first surface of the facing member is made of a hydrophobic material.

13. The substrate treatment device according to claim 1, wherein
the cleaning unit further includes an adjustment mechanism configured to adjust an inclination of the substrate to be treated at a time of the substrate to be treated being stored in the cleaning unit.

14. The substrate treatment device according to claim 1, further including a sensor configured to be capable of measuring a physical property of the cleaning liquid after being supplied, by the cleaning liquid supply mechanism, onto the substrate to be treated.

15. A substrate treatment device comprising:
a substrate-to-be-treated transfer box;
a cleaning unit provided in the substrate-to-be-treated transfer box; and
a load port coupled to the substrate-to-be-treated transfer box, wherein
the cleaning unit includes
a substrate-to-be-treated holding mechanism configured to be capable of holding a substrate to be treated,
a cleaning liquid supply mechanism configured to be capable of supplying cleaning liquid onto the substrate to be treated held by the substrate-to-be-treated holding mechanism, and
a gas supply mechanism configured to be capable of supplying gas onto the substrate to be treated held by the substrate-to-be-treated holding mechanism, and
the substrate-to-be-treated transfer box includes a substrate-to-be-treated transfer mechanism configured to be capable of transferring the substrate to be treated between the load port and the cleaning unit.

16. The substrate treatment device according to claim 15, wherein
the substrate-to-be-treated transfer box further includes a railway extending in a first direction,
the substrate-to-be-treated transfer mechanism includes
a base movable on the railway,
an extension and contraction arm attached onto the base in a rotatable manner, a protruding amount of the extension and contraction arm from the base in a second direction orthogonal to the first direction being adjustable, and
a holding part provided on a distal end side of the extension and contraction arm, and configured to be capable of holding the substrate to be treated,
the cleaning unit further includes
a second substrate-to-be-treated holding mechanism provided at a position apart from the substrate-to-be-treated holding mechanism in a third direction orthogonal to the first direction and the second direction,
a second cleaning liquid supply mechanism configured to be capable of supplying the cleaning liquid onto a second substrate to be treated held by the second substrate-to-be-treated holding mechanism, and
a second gas supply mechanism configured to be capable of supplying the gas onto the second substrate to be treated held by the second substrate-to-be-treated holding mechanism,
the cleaning unit is capable of cleaning the substrate to be treated held by the substrate-to-be-treated holding mechanism, and
the cleaning unit is capable of cleaning the second substrate to be treated held by the second substrate-to-be-treated holding mechanism during cleaning of the substrate to be treated.

17. The substrate treatment device according to claim 15, wherein
the cleaning liquid supply mechanism is capable of supplying the cleaning liquid to an upper surface of the substrate to be treated for a first predetermined period with a relative position between the cleaning liquid supply mechanism and the substrate to be treated being fixed, and
the gas supply mechanism is capable of supplying the gas to the upper surface of the substrate to be treated for a second predetermined period with a relative position between the gas supply mechanism and the substrate to be treated being fixed.

18. The substrate treatment device according to claim 17, wherein
the cleaning unit further includes at least one functional component,
the at least one functional component includes
the cleaning liquid supply mechanism,
the gas supply mechanism, and
a sucking mechanism configured to be capable of sucking the cleaning liquid and the gas, and
the at least one functional component includes a plurality of functional components, and the plurality of functional components are disposed to face the upper surface of the substrate to be treated at least during the first predetermined period or the second predetermined period.

19. The substrate treatment device according to claim 15, wherein
the cleaning liquid supply mechanism is further capable of supplying isopropyl alcohol onto the substrate to be treated after the cleaning liquid is supplied onto the substrate to be treated.

20. The substrate treatment device according to claim 15, wherein
the gas includes a nitrogen gas.

21. The substrate treatment device according to claim 15, wherein
the cleaning unit further includes a facing member having a first surface that faces an upper surface of the substrate to be treated at a time of the substrate to be treated being stored in the cleaning unit,
the cleaning liquid supply mechanism is capable of supplying the cleaning liquid to between the first surface of the facing member and the upper surface of the substrate to be treated, and the gas supply mechanism is capable of supplying the gas to between the first surface of the facing member and the upper surface of the substrate to be treated, and
the first surface of the facing member is made of a hydrophobic material.

22. The substrate treatment device according to claim 15, wherein
the cleaning unit further includes an adjustment mechanism configured to adjust an inclination of the substrate to be treated at a time of the substrate to be treated being stored in the cleaning unit.

23. The substrate treatment device according to claim 15, further including a sensor configured to be capable of measuring a physical property of the cleaning liquid after being supplied, by the cleaning liquid supply mechanism, onto the substrate to be treated.

24. A method for manufacturing a semiconductor device by using
a first device including
a first unit configured to be capable of performing a first process,
a first substrate-to-be-treated transfer box,
a first load port attached to the first substrate-to-be-treated transfer box, and
a cleaning unit attached to the first substrate-to-be-treated transfer box,
a second device including
a second unit configured to be capable of performing a second process,
a second substrate-to-be-treated transfer box, and
a second load port attached to the second substrate-to-be-treated transfer box, and
a ceiling traveling transfer vehicle, wherein
the cleaning unit is capable of performing a cleaning process by using
a substrate-to-be-treated holding mechanism configured to be capable of holding a substrate to be treated,
a cleaning liquid supply mechanism configured to be capable of supplying cleaning liquid onto the substrate to be treated held by the substrate-to-be-treated holding mechanism, and
a gas supply mechanism configured to be capable of supplying gas onto the substrate to be treated held by the substrate-to-be-treated holding mechanism, and
the method comprises
performing, by using the first unit, the first process on the substrate to be treated,
transferring the substrate to be treated on which the first process is performed from the first unit to the cleaning unit by using the first substrate-to-be-treated transfer box,
performing, by using the cleaning unit, the cleaning process on the substrate to be treated on which the first process is performed,
transferring the substrate to be treated on which the cleaning process is performed from the cleaning unit to the first load port by using the first substrate-to-be-treated transfer box,
transferring the substrate to be treated on which the cleaning process is performed from the first load port to the second load port by using the ceiling traveling transfer vehicle,
transferring the substrate to be treated on which the cleaning process is performed from the second load port to the second unit by using the second substrate-to-be-treated transfer box, and
performing, by using the second unit, the second process on the substrate to be treated on which the cleaning process is performed.
